(19) United States
(12) Patent Application Publication
(10) Pub. No.: US 2002/0151138 A1
(43) Pub. Date: Oct. 17, 2002

(54) Method for fabricating an NROM

(76) Inventor: Chien-Hung Liu, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,304

(22) Filed: Apr. 10, 2002

(30) Foreign Application Priority Data
Apr. 13, 2001 (TW) 090108892

(51) Int. Cl. H01L 21/336

(52) U.S. Cl. 438/261; 438/258; 438/287

(57) ABSTRACT

Nitride read only memory (NROM) fabrication begins with a substrate with a surface of the substrate having at least one memory area and one peripheral area. An oxide-nitride-oxide (ONO) layer, containing a bottom oxide layer, a silicon nitride layer and a top oxide layer, is formed to cover both the memory area and the periphery area. Multiple columns of bit line masks are then located on the ONO layer of the memory area. Numerous ion implantation and etching processes are performed on the substrate to finally form multiple rows of word lines, being approximately perpendicular to the bit lines, on the ONO layer.

### BACKGROUND OF INVENTION

1. Field of the invention

The present invention relates to a method for fabricating a nitride read only memory (NROM), and more specifically, to a method for forming an NROM with an ultra shallow doping region.

2. Description of the Prior Art

Nitride read only memory (NROM) is a semiconductor device used to store data that is comprised of a plurality of memory cells. Each memory cell comprises a metal-oxide semiconductor (MOS) transistor and a gate dielectric layer of oxide-nitrogen-oxide (ONO) structure. Since the silicon nitride layer of the ONO gate dielectric layer gate is highly compact, hot electrons tunneling through a MOS transistor into the silicon nitride layer are trapped. As a result the silicon nitride layer may be used as a floating gate for storing data.

Please refer to FIG. 1 to FIG. 6. of cross-sectional views of forming an NROM cell according to the prior art. As shown in FIG. 1, an NROM cell is formed on the surface of a P-type silicon substrate 10. The prior art method first performs an ONO process on the surface of the P-type silicon substrate 10 to form an ONO dielectric layer 18 composed of a bottom oxide layer 12, a silicon nitride layer 14 and a top oxide layer 16. A photolithographic process is employed to form a photoresist layer 20 on the surface of the ONO dielectric layer 18. The photoresist layer 20 forms patterns to define positions of bit lines.

As shown in FIG. 2, the photoresist layer 20 is used as a mask for performing an anisotropic etching process to remove the top oxide layer 16 and the silicon nitride layer 14 not covered by the photoresist layer 20. Following that, an ion implantation process 22 is performed to form a plurality of N-type doped areas 24 in the silicon substrate 10 that function as bit lines, i.e. buried drains of the memory device. Two neighboring doped areas 24 define a channel, and the distance between the two neighboring doped areas 24 is defined as channel length. The ion implantation process 22 is performed perpendicular to the surface of the silicon substrate 10 using an arsenic (As) ion concentration of 1×10¹⁴˜1×10¹⁶/cm² and having an energy ranging from 20 KeV to 200 KeV at room temperature.

As shown in FIG. 3, an ion implantation process with a first oblique angle 26 is performed to form a P-type pocket doped area 28 on one side of each doped area 24. As shown in FIG. 4, an ion implantation process with a second oblique angle 27 is performed to form a P-type pocket doped area 29 on the other side of each doped area 24. The two ion implantation processes 26 and 27 have approximately the same ion implantation parameters.

The two ion implantation processes have a first oblique angle 26 and a second oblique angle 27, the angles both ranging from 20° to 45°. Both implantation processes use BF₂⁺ as a dopant, with a dosage ranging from 1×10¹³/cm² to 1×10¹⁶/cm², and energy ranging from 20 KeV to 150 KeV. Under these parameters, the BF₂⁺ dopants mostly concentrate in the silicon substrate 10 to a depth of about 1000 Angstroms (Å) under the channel. The advantage of forming P-type doped areas 28 and 29 is that it provides a high electric field area on one side of the channel. The high electric field area can increase the speed of electrons passing through the channel during a programming process. In other words, electrons accelerated to higher speeds can obtain enough kinetic energy to pass through the oxide layer 12 into the silicon nitride layer 14 by way of collision or scattering, so as to improve programming efficiency.

As shown in FIG. 5, a photoresist ashing process (or a photoresist stripping process) is performed to remove the photoresist layer 20. The prior art method to remove the photoresist layer 20 is performed in a plasma processing chamber. The plasma processing generally comprises a top electrode, which is normally connected to a RF generator, and a bottom electrode, which is usually grounded. A mixed photoresist ashing gas comprising oxygen and helium is used to generate plasma so as to quickly clean away the photoresist layer 20.

As shown in FIG. 6, a thermal oxidation method with a temperature of 700° C.˜1150° C. is employed to form a bit line oxide layer 32 on a top surface of the bit lines 24 so as to separate each silicon nitride layer 14. Finally, a doped polysilicon layer 34 is deposited and functions as a word line. The dopants implanted into the silicon substrate 10 previously, including the dopants in the doped areas 24, 28 and 29, can be activated during the formation of the bit line oxide layer 32.

However, two ion implantation processes, having a first oblique angle 26 and a second oblique angle 27, respectively, lead to several problems. Neither the doped areas 28 and 29 of p-type have a distributed depth of doped concentration at a short distance, less than 500 angstroms, away from the surface of the silicon substrate 10 so as to improve programming efficiency. In addition, the diffusion profile of the dopants is difficult to control due to the sloping concentration distribution of the dopants in the doped areas 28 and 29 after the bit line oxide layer 32 is formed by performing the thermal oxidation process. Besides, a complicated calculation is needed to precisely control the required concentration distribution, diffusion profile of the dopants, parameters of the ion implantation processes, including the first and second oblique angles 26 and 27, implantation energies and dosages. The production window is thus reduced. Consequently, the production cost is increased as well.

### SUMMARY OF INVENTION

It is therefore a primary object of the present invention to provide a method for fabricating a nitride read only memory (NROM) so as to improve the programming efficiency of the NROM.

It is another object of the present invention to provide a method for fabricating a NROM with ultra-shallow doped areas so as to improve the programming efficiency of the NROM.

It is another object of the present invention to provide a method for fabricating a NROM both to simultaneously simplify the processes and increase the production window so as to improve the product reliability.

According to the claimed invention, a substrate with a surface comprising at least one memory area and one peripheral area is provided in a method for fabricating a NROM. An oxide-nitride-oxide (ONO) layer, comprising a bottom oxide layer, a silicon nitride layer and a top oxide layer, is formed to cover both the memory area and the periphery area. Multiple columns of bit line masks are then formed on the ONO layer of the memory area. By performing a first ion implantation process of a first conductive type, a plurality of bit lines of the first conductive type is formed within the substrate not covered by the bit line masks. An etching process is then performed to etch the bit line masks to a predetermined depth. By performing a second ion implantation process of the second conductive type approximately perpendicular to the ONO layer, a plurality of ultra-shallow doped areas of the second conductive type is formed within the substrate not covered by the bit line masks. Finally, the bit line masks are removed and a plurality of rows of word lines, approximately perpendicular to the bit lines, is formed on the ONO layer at the end of the method.

It is an advantage of the present invention that after the etching process, the bit line masks still have enough thickness to function as implantation masks in the subsequent ion implantation process. In addition, the ultra-shallow doped areas, having a doped depth smaller than 500 angstroms and a bottom width of the doped channel of approximately 100 angstroms, are close to the surface of the substrate and helpful to produce hot carrier. Therefore, the programming efficiency of the NROM is significantly improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 6 are the cross-sectional views of forming an NROM cell according to the prior art.

FIG. 7 to FIG. 11 are the cross-sectional views of forming an NROM cell according to the present invention.

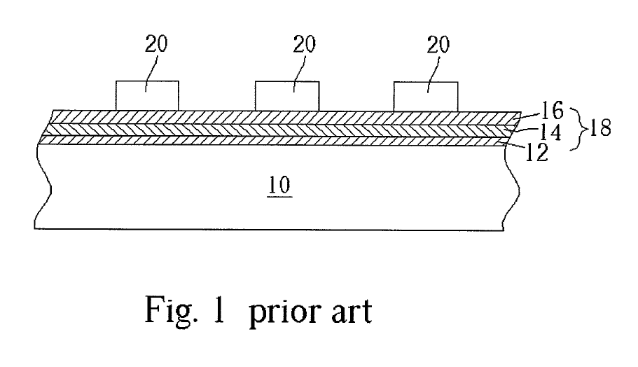

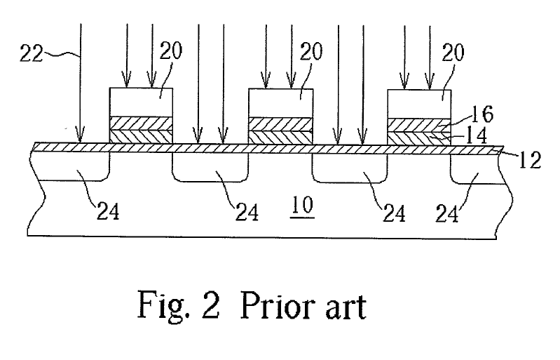

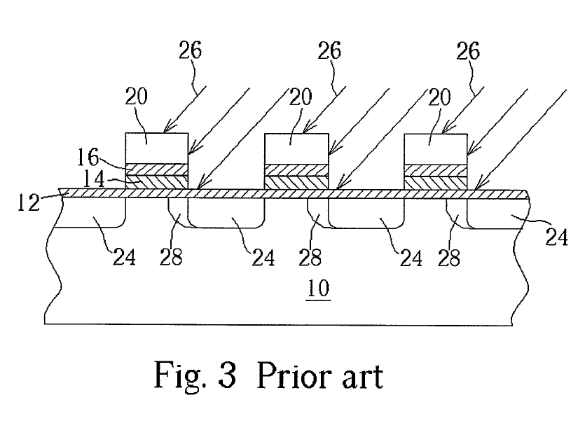

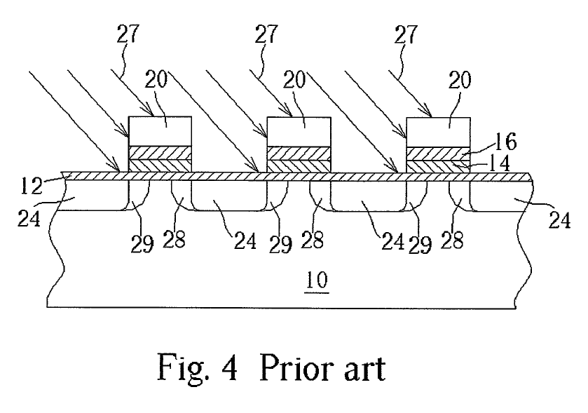

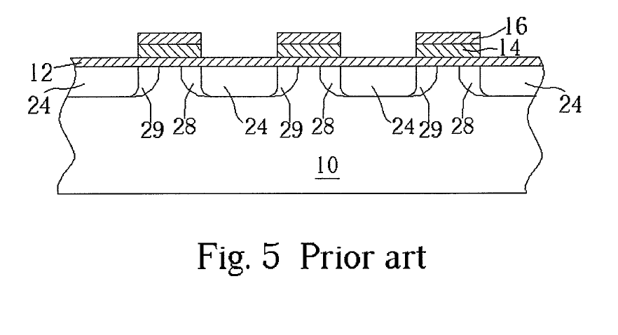

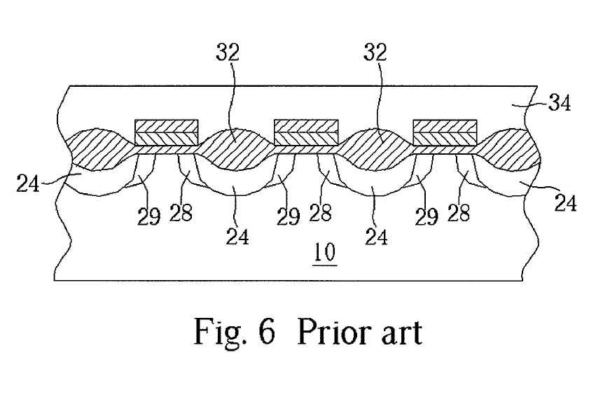

### DETAILED DESCRIPTION

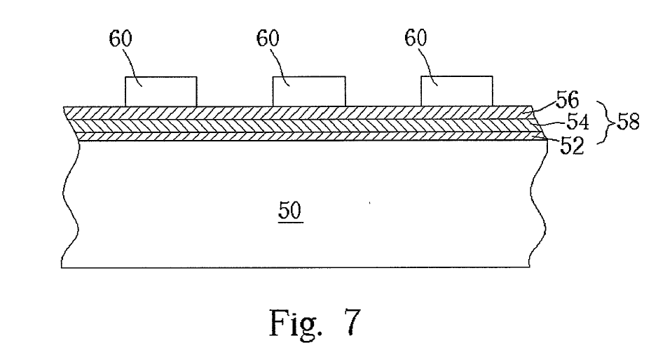

Please refer to FIG. 7 to FIG. 11 of the cross-sectional views of forming an NROM cell according to the present invention. As shown in FIG. 7, an oxide-nitride-oxide (ONO) process is performed to form an ONO layer 58, having a thickness ranging from 150 to 250 angstroms, on a surface of a silicon substrate 50, further comprising at least a memory area and a peripheral area. For simplicity of the description, only portions of the memory area relative to the present invention are revealed in FIG. 7 to FIG. 11. The ONO layer 58 further comprises a bottom oxide layer 52, having a thickness ranging from 50 to 150 angstroms, a silicon nitride layer 54, having a thickness ranging from 20 to 150 angstroms, and a top oxide layer 56, having a thickness ranging from 50 to 150 angstroms. A lithography process is then performed to form a photoresist layer 60, employed to define patterns of a buried drain or bit lines, on the ONO layer 58. In the preferred embodiment of the present invention, the silicon substrate is a P-type silicon substrate with the <100> bottom surface. The method of the present invention is applied not only to the P-type silicon substrate but also to others like the silicon-on-insulator (SOI) substrate, comprising a P-type silicon layer and an insulator layer (both not shown), made by a separation by implantation oxygen (SIMOX) process. The method of fabricating the SOI substrate, normally having a thickness ranging from 0.5 to 3 microns, is not the major element of the present invention and is omitted in the following discussion.

In the preferred embodiment of the present invention, the photoresist layer 60, such as the UV-6 model produced by the SHIPLY Company, has an approximate thickness of 6000 angstroms. An anti-reflection coating (not shown) is normally coated on the ONO layer 58 prior to the formation of the photoresist layer 60 so as to prevent the standing wave effect and keep a wall on either side of the photoresist layer 60 smooth and vertical. Alternatively, the photoresist layer 60 is the DUV-44 model, having an coating thickness of approximately 600 angstroms, produced by the NISSAN CHEMICAL Company. Generally a normal based (C, H, O, N based) mask layer is applicable in the present invention.

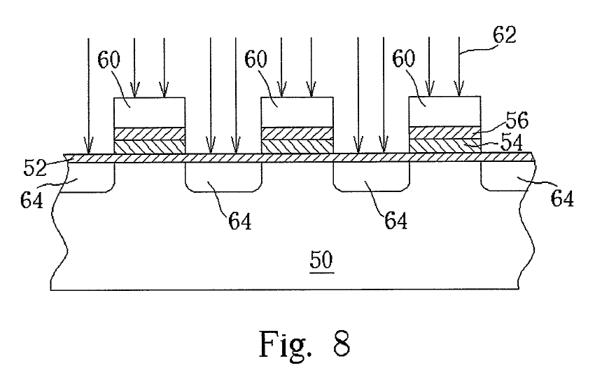

As shown in FIG. 8, an anisotropic dry etching process, using the photoresist layer 60 as a mask, is performed to remove portions of the top oxide layer 56 and portions of the silicon nitride layer 54, not covered by the photoresist layer 60. An ion implantation process 62 is then performed to form multiple doped areas 64 of n-type, employed as bit lines of the memory, in the silicon substrate 50. A channel is defined as a space between two neighboring doped areas 64 and a channel length is thus defined as the distance between two neighboring doped areas 64. The dosage of the ion implantation process, using arsenic (As) ions as primary dopants to perpendicularly dope the silicon substrate 50 at a room temperature, is 1×10¹⁴ to 1×10¹⁶ cm⁻² with an implantation energy ranging from 20 to 200 KeV. In another embodiment of the present invention, other n-type ions, including phosphorous (P) ions, are employed as the dopants of the ion implantation process.

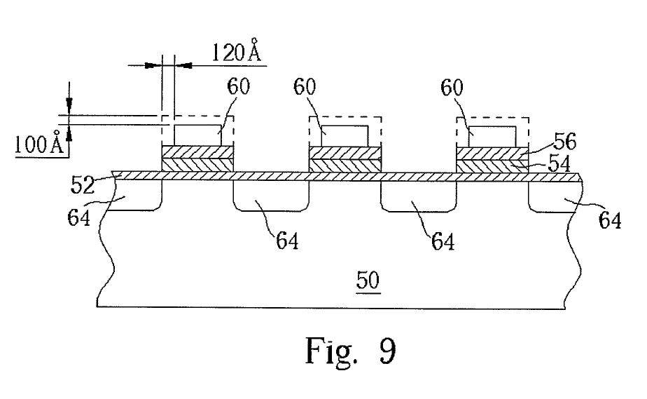

As shown in FIG. 9, an oxide plasma etching process is performed to remove portions of the photoresist layer 60 so as to reduce the thickness of the photoresist layer 60 to a thickness ranging from 5800 to 5900 angstroms. The removed portions of the wall on either side of the photoresist layer 60 have a thickness ranging from 80 to 200 angstroms. The preferred removed thickness of portions of the wall on either side of the photoresist layer 60 ranges from 50 to 150 angstroms. In the preferred embodiment of the present invention, portions of the wall, with a thickness of 120 angstroms, on either side of the photoresist layer 60 are removed. The removal thickness of the wall of the photoresist layer 60, as well as parameters, including oxygen flow rate, pressure, distance between the upper and bottom electrodes and RF power, of the oxide plasma etching process, need to be determined before performing the oxide plasma etching process so as to achieve a required width of a pocket doped area in subsequent processes. Most importantly, both vertical and horizontal removal rates of the photoresist layer 60 need to be precisely controlled so as to prevent a quick removal of the photoresist layer 60. Thus traditionally used photoresist stripping systems, normally designed to remove the photoresist at a high removal rate, are not practical in the present invention.

In the preferred embodiment of the present invention, the Rainbow 4400 model produced by Lam Research Corporation is employed in the oxide plasma etching process. The removal rate of the photoresist layer 60 is thus controlled so as to keep the wall on either side of the photoresist layer 60 smooth and achieve the required thickness of the remaining portions of the wall on either side of the photoresist layer 60. Other apparatuses as well as the Rainbow 4000 model are applicable in the present invention. The Rainbow 4000 model comprises a sealed plasma chamber. The flow rate of the pure oxygen, without adding any bombardment gas, such as helium, supplied to the sealed plasma chamber, the operating pressure and the RF power of the upper electrode are controlled within the ranges of 100 to 200 standard cubic centimeters per minute (sccm), 500 to 1000 mTorr and 300 to 750 W, respectively. The removal rate of the photoresist layer 60 is thus controlled within the range of 100 to 200 angstroms per minute under the above conditions. The method of the present invention is applied not only with the previously mentioned photoresist stripping system and parameters of the oxide plasma etching process in the preferred embodiment of the present invention, but also with another similar photoresist stripping system and parameters of the oxide plasma etching process leading to similar results.

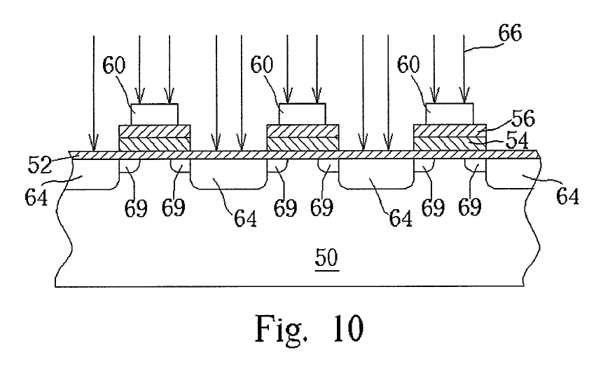

As shown in FIG. 10, a vertical ion implantation process 66, using boron (B) or BF₂ ions as dopants, is performed to form a pocket doped area 69 of p-type adjacent to either side of each doped area 64. The dosage of the vertical ion implantation process 66, using BF₂ions as dopants to perpendicularly dope the silicon substrate 50, is 1×10¹³ to 1×10¹⁵ cm⁻² with an implantation energy ranging from 10 to 80 KeV. The pocket doped area 69 of p-type has a distributed depth of doped concentration less than 500 angstroms within the channel, having the channel length ranging from 80 to 200 angstroms based on the removal thickness of the photoresist layer 60, in the silicon substrate 50. The pocket doped area 69 of p-type is close to the surface of the silicon substrate 50 and helpful to produce hot carriers so as to improve the programming efficiency of the NROM.

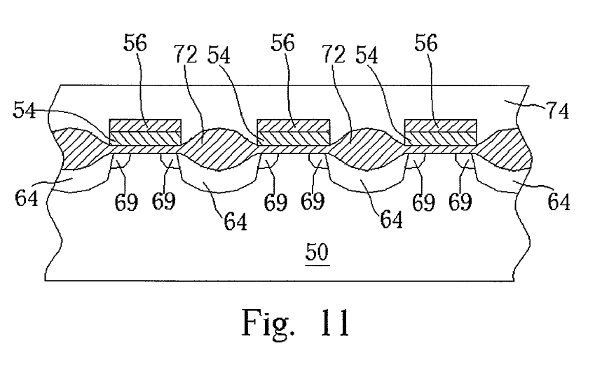

As shown in FIG. 11, a thermal oxidation process with a operating temperature of 700° C.˜1150° C. is employed to form a bit line oxide layer 72 on a top surface of the bit lines 64 so as to separate each silicon nitride layer 54. Finally, a doped polysilicon layer 74 is deposited and functions as a word line. The dopants previously implanted into the silicon substrate 50, including the dopants in the doped areas 64 and 69, can be activated during the formation of the field oxide layer 72.

The method of the present invention has the following advantages: (1) Portions of the pocket doped area 69 of p-type having a distributed depth of doped concentration is only a short distance, less than 500 angstroms, away from the surface of the silicon substrate 50 so as to achieve a maximum programming efficiency of the NROM.

(2) The pocket doped area 69 of p-type is formed by performing a vertical ion implantation process 66 to have a horizontal distribution concentration. Thus the diffusion profile of the dopants is easy to control.

(3) The pocket doped area 69 of p-type is formed by performing a vertical ion implantation process 66 so as to increase the production window of the NROM.

In comparison with the prior art, portions of the photoresist layer 60 are removed and the vertical ion implantation process 66 is employed in the present invention. Thus the pocket doped area 69 of p-type is close to the silicon nitride layer so as to improve the programming efficiency of the NROM.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method for fabricating a nitride read only memory (NROM), the method comprising:
providing a substrate, with the surface of the substrate comprising at least one memory area and one peripheral area;
forming an oxide-nitride-oxide (ONO) layer to cover both the memory area and the periphery area, the ONO layer comprising a bottom oxide layer, a silicon nitride layer and a top oxide layer;
forming a plurality of columns of bit line masks on the ONO layer of the memory area;
performing a first ion implantation process of the first conductive type to form a plurality of bit lines of the first conductive type within the substrate not covered by the bit line masks;
etching the bit line masks to a predetermined depth, with the remaining bit line masks still having enough thickness to function as implantation masks in the subsequent ion implantation process;
performing a second ion implantation process of the second conductive type approximately perpendicular to the ONO layer to form a plurality of ultra-shallow doped areas of the second conductive type within the substrate not covered by the bit line masks;
removing the bit line masks; and
forming a plurality of rows of word lines on the ONO layer, the word lines being approximately perpendicular to the bit lines;
wherein the ultra-shallow doped areas being close to the surface of the substrate and helpful to produce hot carrier so as to improve the programming efficiency of the NROM.

2. The method of claim 1 wherein before forming the bit line masks the method further comprises:
forming at least one mask on the ONO layer of the memory area;
performing a second ion implantation process to adjust a dopant concentration of the substrate not covered by the mask; and removing the mask.

3. The method of claim 1 wherein the ONO layer is 150 to 250 angstroms (Å) thick, the bottom oxide layer is 50 to 150 Å thick, the silicon nitride layer is 20 to 150 Å thick, and the top oxide layer is 50 to 150 Å thick.

4. The method of claim 1 wherein the bit line masks comprise photoresist materials.

5. The method of claim 1 wherein the substrate is a silicon-on-insulator (SO) substrate.

6. The method of claim 1 wherein the substrate is a silicon substrate.

7. The method of claim 1 wherein the plurality of ultra-shallow doped areas of second conductive type are next to the bit lines.

8. The method of claim 1 wherein the plurality of ultra-shallow doped areas of second conductive type have a distributed depth of doped concentration less than 500 angstroms (Å).

9. The method of claim 1 wherein the plurality of ultra-shallow doped areas of second conductive type have doped depth smaller than 500 angstroms (Å), and the bottom width of doped channel is about 100 angstroms (Å).

10. The method of claim 1 wherein the first conductive type is N-type, and the second conductive type is P-type.

11. The method of claim 1 wherein the first ion implantation process uses phosphorous (P) or arsenic (As) ions as primary dopants.

12. The method of claim 1 wherein the second ion implantation process uses boron (B) or BF₂ ions as dopants.

13. The method of claim 1 wherein the predetermined depth is about 100 to 150 angstroms (Å).
